(19) United States
(12) Patent Application Publication
(10) Pub. No.: US 2026/0357956 A1
(43) Pub. Date: Nov. 12, 2026

(54) LIGHTING DEVICE FOR A MOTOR VEHICLE

(71) Applicant: VALEO VISION, Bobigny (FR)

(72) Inventors: Joel LI, Bobigny (FR); Stephane ANDRE, Bobigny (FR); Nicolas MARTIN, Bobigny (FR)

(73) Assignee: VALEO VISION, Bobigny (FR)

(21) Appl. No.: 19/139,943

(22) PCT Filed: Dec. 19, 2023
(86) PCT No.: PCT/EP2023/086500

§ 371 Date: Jun. 17, 2025

(30) Foreign Application Priority Data
Dec. 19, 2022 (FR) FR2213759

(51) Int. Cl. F21K 9/60; F21V 19/00

(52) U.S. Cl. CPC F21K 9/60; F21V 19/0015

(57) ABSTRACT

The invention relates to a lighting device. The lighting device includes an optical device and a first printed circuit board with a light source attached. The lighting device includes a light-emitting region and a protective housing surrounding the light-emitting region. A first height of the protective housing relative to a planar surface of the first printed circuit board, measured in a first direction toward the optical device perpendicular to the planar surface, being greater than a second height of the light-emitting region relative to the planar surface measured in the first direction. A first surface of the housing, which is oriented toward the light-emitting region and included between the first height and the second height, is defined so as to prevent rays from the light-emitting region from reflecting off the first surface and reaching the optical device.

### TECHNICAL FIELD

The invention relates to a luminous device for an automotive vehicle.

### BACKGROUND OF THE INVENTION

Nowadays, automotive vehicle optical systems comprise ultra-pixelated LED light sources that make it possible to display images with varied shapes. However, the use of such a light source in a vehicle optical system may produce undesirable effects.

Specifically, the sharpness of the images projected by the light source may be adversely affected by phenomena whereby the rays coming from the light ray emitting zone are reflected on elements situated in the optical system and in the vicinity of the light ray emitting zone. In particular, light reflections may be caused by a reflective surface of a protective housing, said reflective surface overhanging the light ray emitting zone of the light source.

### SUMMARY OF THE INVENTION

The object of the invention is to provide a luminous device that makes it possible to overcome the constraints described above. In particular, the invention makes it possible to produce a luminous device that is simple and reliable and makes it possible to filter light reflections on a protective housing bordering the light ray emitting zone of the luminous device.

To this end, the invention relates to a luminous device comprising an optical device and a first printed circuit board to which a light source, which comprises a light ray emitting zone and a protective housing surrounding the light ray emitting zone, is fastened, a first height of the protective housing relative to a flat surface of the first printed circuit board, measured in a first direction directed toward the optical device perpendicular to said flat surface, being strictly greater than a second height of the light ray emitting zone relative to the flat surface measured in the first direction. In addition, a first surface, which is oriented toward the light ray emitting zone and included between the first height and the second height, of the housing is defined so as to prevent rays coming from the light ray emitting zone from being reflected on said first surface and reaching the optical device.

In one embodiment of the luminous device, the housing covers and/or protects electrical connections connecting the first printed circuit board to the light source and/or the first height is determined by the size of the electrical connections.

In one embodiment of the luminous device, the first surface is a flat surface extending between the light ray emitting zone and an upper surface of the housing. In addition, the first surface is perpendicular both to the light ray emitting zone and to the upper surface, a first angle formed between the first surface and the upper surface being equal to 90 degrees and having a rounded profile with a radius that is strictly less than 50 micrometers.

In one embodiment of the luminous device, the first surface is a flat surface bordering the light ray emitting zone and a second angle formed between the first surface and the light ray emitting zone is strictly greater than 160 degrees or
the second angle is strictly less than 90 degrees.

In one embodiment of the luminous device, the first surface is grained and the roughness of graining of the first surface is strictly greater than 8 micrometers.

In one embodiment of the luminous device, a groove is formed in an upper surface of the housing in the vicinity of the first surface, and the groove delimits a housing tab supporting the first surface.

In one embodiment of the luminous device, the housing tab extends above the first surface.

In one embodiment of the luminous device, the first surface is convex, and a center of curvature of the first surface and the light source are situated on the same side of the first surface.

### BRIEF DESCRIPTION OF DRAWINGS

The appended drawings show, by way of example, an embodiment of a luminous device according to the invention.

FIG. 1 schematically shows an embodiment of a luminous device according to the invention.

FIG. 2 schematically shows a view in cross section of a printed circuit board to which a light ray emitting zone and a protective housing are fastened.

FIG. 3 illustrates an embodiment of a light source.

FIG. 4 illustrates light reflections on a protective housing in an embodiment of the housing without implementation of the invention.

FIG. 5 shows a protective housing according to a first embodiment of the invention.

FIG. 6 illustrates light reflections on a protective housing according to the first embodiment of the invention.

FIG. 7 shows a protective housing according to a second embodiment of the invention.

FIG. 8 illustrates light reflections on a protective housing according to the second embodiment of the invention.

FIG. 9 shows a protective housing according to a third embodiment of the invention.

FIG. 10 illustrates light reflections on a protective housing according to the third embodiment of the invention.

### DETAILED DESCRIPTION OF THE INVENTION

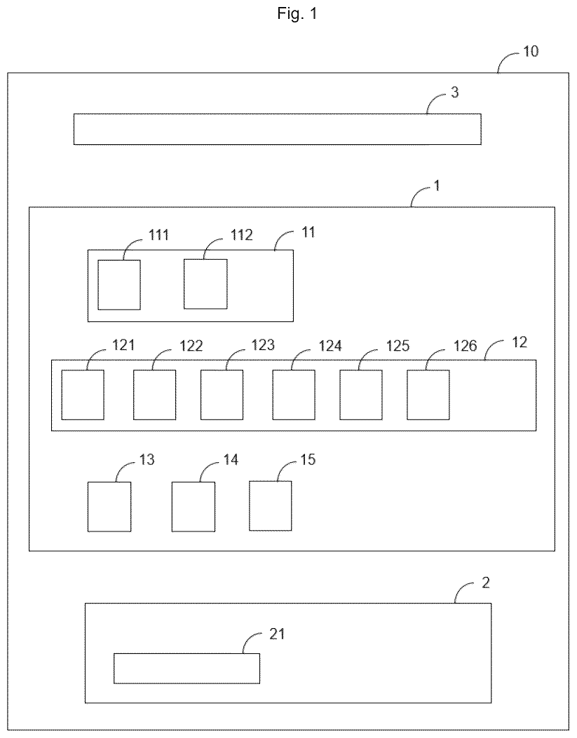

A first embodiment of a luminous device according to the invention is shown in FIG. 1.

The luminous device 10 primarily comprises
a light source 1 comprising a light ray emitting zone 11, and a protective housing 12 surrounding the light ray emitting zone 11,
a first printed circuit board 2 having a surface 21 to which the light ray emitting zone 11 and the protective housing 12 are fastened, and
an optical device 3, which may be a lens, for example.

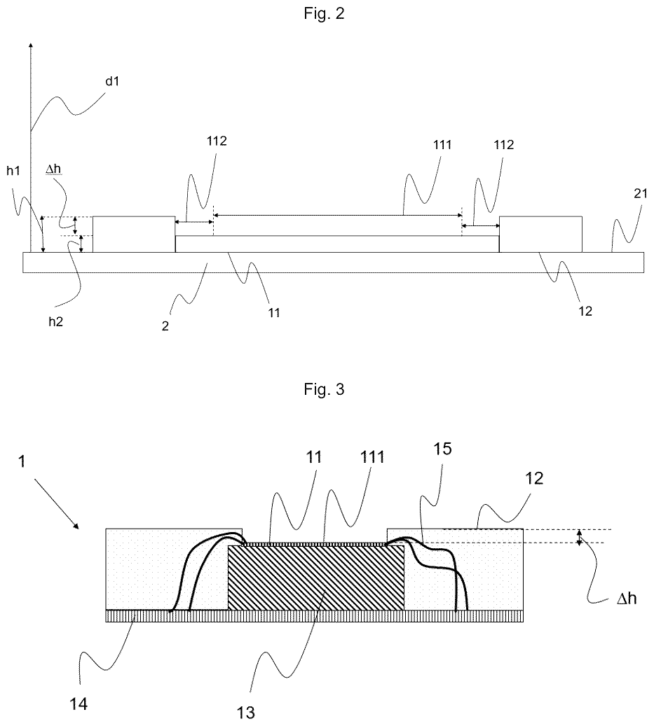

Preferentially, the light source 1 is an LED, the structure of which is detailed in FIGS. 2 and 3. As a note, in FIGS. 2 and 3, the housing 12 is shown according to a first embodiment, which is described later on in the document. In addition, other embodiments of the housing 12, in particular a second and a third embodiment, are also described later on in this document.

FIG. 2 provides a first schematic depiction of the light ray emitting zone 11 surrounded by the protective housing 12.

The light ray emitting zone 11 is divided into a first zone 111, referred to as active zone, comprising photon-emitting matter, and a second zone 112, referred to as technical zone, not comprising any photon-emitting matter.

The active zone 111 comprises physical matter that emits photons when an electric current passes through it, thus generating blue light. The active zone 111 also comprises a phosphor layer that transforms blue light into white light.

The active zone 111 is also called a “matrix of pixels”. The photon-emitting matter is divided into pixels. Each pixel can be controlled individually to emit photons. Each pixel of the matrix 111 is able to emit light rays over 180 degrees. In one embodiment, the matrix of pixels 111 may comprise 25000 pixels.

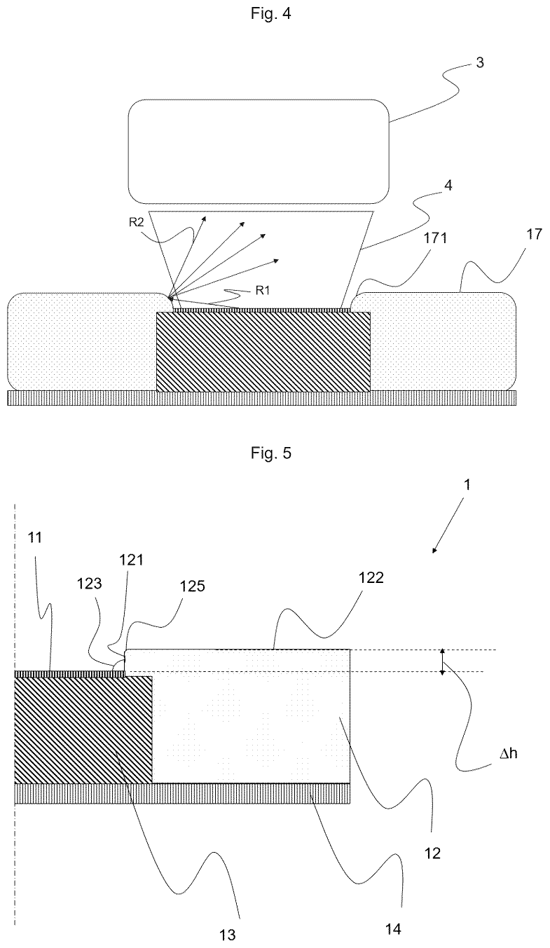

The active zone 111 defines an emission cone 4 of the light source, the emission cone being shown more specifically in FIG. 4. In order to project the sharpest possible luminous zone, the light rays contained in the emission cone 4 must come directly from the active zone 111. In other words, it is not desirable for reflected rays to be contained in the emission cone 4.

The technical zone 112 is situated at the periphery of the active zone 111. In other words, the technical zone 112 is a thin strip that borders the periphery of the active zone 111 and does not emit any light. The order of magnitude of the width of the technical zone 112 is 500 microns, or even 300 microns.

In a preferred embodiment, the protective housing 12 is a protective resin 12 molded around the technical zone 112.

In the remainder of the document, the terms “protective housing” and “protective resin” are used interchangeably.

The light ray emitting zone 11 and the protective resin 12 are fastened to a flat surface 21 of the first printed circuit board 2.

A first direction d1 is defined perpendicular to the flat surface 21 of the first printed circuit board 2, the direction d1 being oriented toward the optical device 3.

In the embodiment described, a first height h1 of the protective resin 12 relative to the flat surface 21, measured in the first direction d1, is strictly greater than a second height h2 of the light ray emitting zone 11 relative to the flat surface 21, measured in the first direction d1. In other words, the height h1 of the protective resin 12 exceeds the height h2 of the light ray emitting zone 11. For example, the height h1 is strictly greater than the height h2, the difference Ah between the two heights being able to be, for example, 0.2 to 0.3 mm.

FIG. 3 schematically shows the light source 1, or LED 1, comprising the light ray emitting zone 11 and the protective resin 12 that are described above. In this more detailed view, the structure of the LED 1 appears more precisely. In particular, the matrix of pixels 111 is shown associated with a matrix of switches 13.

The LED 1 also comprises a second printed circuit board 14 intended to control the matrix of switches 13. The assembly formed by the matrix of pixels 111 and the matrix of switches 13 is fastened to the second printed circuit board 14, for example by soldering.

The second printed circuit board 14 makes it possible to independently control the state of each pixel of the LED 1 as being illuminated or switched off. A network of wired connections 15 makes it possible to control each of the pixels. The wired connections 15 are positioned between the emitting surface 11 and the second printed circuit board 14.

The protective resin 12 has the role of protecting the network of wired connections 15. To this end, the protective resin 12 completely envelops the network of wired connections 15. Thus, the height difference Ah between the emitting surface 11 and the protective resin 12 is due to the volume occupied by the network of wired connections 15 and to the excess thickness of resin required to envelope the ends of the wired connections 15 that are connected to the emitting surface 11.

In addition, for better thermal insulation of the network of wired connections, the protective resin is preferentially light in color, so as not to absorb heat.

The overthickness of the protective resin 12, and its ability to reflect light contribute to generating parasitic light reflections in the LED 1. Specifically, in an embodiment described in FIG. 4 of a housing 17 without implementation of the invention, the housing 17 may comprise an at least partially rounded surface 171 bordering the emitting surface 11. Thus, without implementation of the invention, the geometry of the housing 17 can allow a light ray R1 coming from the emitting zone 11 to be reflected on a surface of the housing, in particular on a rounded edge of the housing 17 and to generate a beam of rays R2, some rays being contained in the cone 4 and reaching the optical device 3.

In order to limit the quantity of reflected light rays reaching the optical device 3, a housing 12 according to the invention comprises a first surface 121, which is oriented toward the light ray emitting zone 11 and included between the first height h1 and the second height h2, the first surface being defined so as to prevent rays coming from the light ray emitting zone 11 from being reflected on said first surface 121 and reaching the optical device 3.

In one advantageous embodiment, all the surfaces 121, which are oriented toward the light ray emitting zone 11 and included between the first height h1 and the second height h2, of the housing are defined so as to prevent rays coming from the light ray emitting zone 11 from being reflected on these surfaces 121 and reaching the optical device 3.

In the remainder of the document, the term “surface 121” or “first surface 121” refers to the one or more first surfaces 121 defined so as to prevent rays coming from the light ray emitting zone 11 from being reflected on these surfaces 121 and reaching the optical device 3.

With reference to FIGS. 5 to 10, various embodiments of the surface 121 are described below. In the embodiments described, the first surface 121 is a flat surface bordering the light ray emitting zone 11.

A first embodiment of the surface 121 is detailed in FIG. 5. In this embodiment, the first surface 121 extends between the light ray emitting zone 11 and an upper surface 122 of the housing 12. In addition, the first surface 121 is perpendicular both to the light ray emitting zone 11 and to the upper surface 122. Furthermore, a first angle 123 formed between the first surface 121 and the upper surface 122 is equal to 90 degrees. In addition, the first angle 123 has a rounded portion 125 with a radius that is strictly less than 50 micrometers.

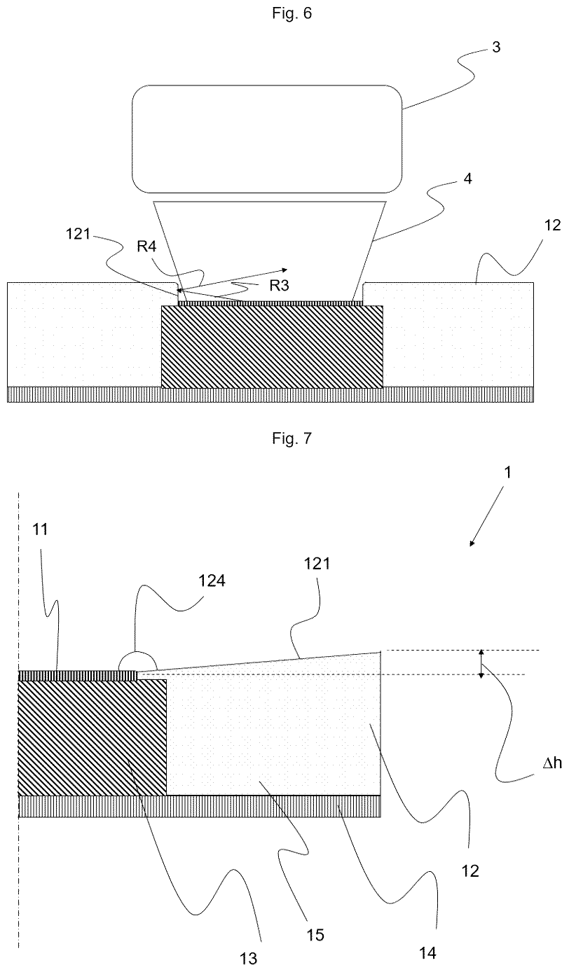

As illustrated in FIG. 6, in the first embodiment of the invention, a ray R3 coming from the emitting zone 11 can be reflected on the first surface 121. In this case, the reflection generates a reflected ray R4, which is substantially symmetrical to the ray R3 along an axis of symmetry perpendicular to the surface 121. The ray R4 produced in this way passes through the cone 4 without reaching the optical device 3.

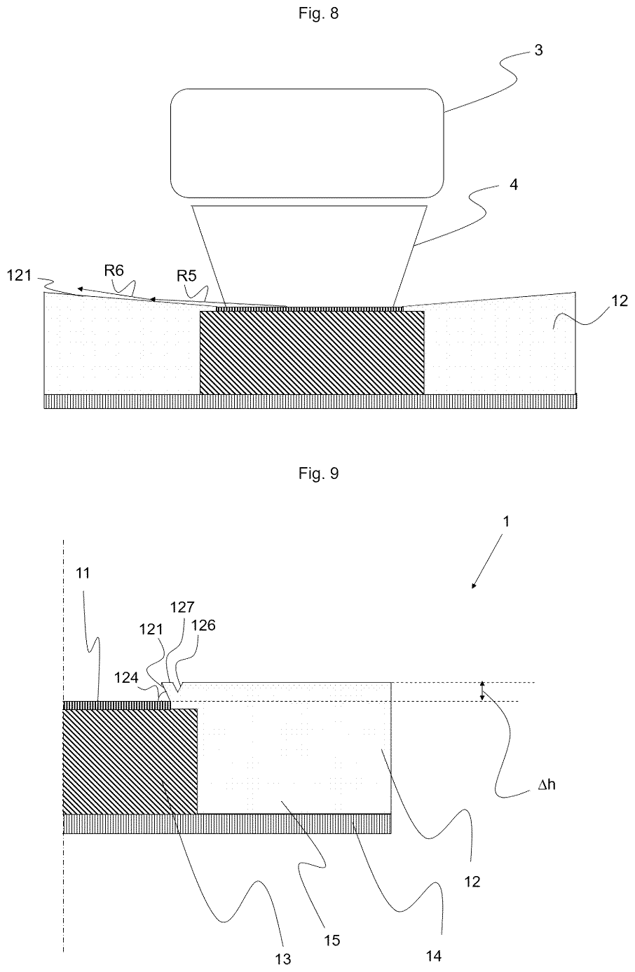

A second embodiment of the surface 121 is detailed in FIG. 7. In this embodiment, a second angle 124 formed between the first surface 121 and the light ray emitting zone 11 is strictly greater than 135 degrees, or even 140 degrees, or even 150 degrees. Thus, grazing rays coming from the emitting zone-that is to say rays having a path close to the first surface 121 are reflected in a zone outside the luminous device.

Specifically, as illustrated in FIG. 8, in the second embodiment of the invention, a ray R5 coming from the emitting zone 11 can be reflected on the first surface 121. In this case, the reflection generates a reflected ray R6, which is substantially symmetrical to the ray R5 along an axis of symmetry perpendicular to the surface 121. The ray R6 produced in this way is directed toward the outside of the luminous device 10. The ray R6 therefore does not reach the optical device 3.

A third embodiment of the surface 121 is detailed in FIG. 9. In this embodiment, the second angle 124 formed between the first surface 121 and the light ray emitting zone 11 is strictly less than 90 degrees. Advantageously, a V-shaped groove 126 is formed in the upper surface 122 of the housing 12 in the vicinity of the surface 121. The groove 126 delimits a housing tab 127 supporting the surface 121 as well as a free space imparting flexibility to the housing tab 127. Specifically, since the housing 12 is preferentially produced by molding, it is advantageously designed so that it can be easily demolded. In the embodiment described, the flexibility of the tab 127 and the free space created by the groove 126 enable the housing 12 to be demolded.

Preferentially, the housing tab 127 extends above the first surface 121.

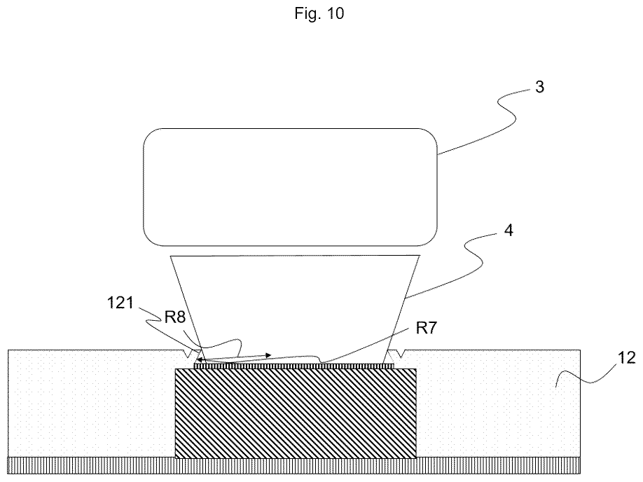

As illustrated in FIG. 10, in the second embodiment of the invention, a ray R7 coming from the emitting zone 11 can be reflected on the first surface 121. In this case, the reflection generates a reflected ray R8, which is substantially symmetrical to the ray R7 along an axis of symmetry perpendicular to the surface 121. The ray R8 produced in this way is confined to a zone close to the emitting zone 11. The ray R8 therefore does not reach the optical device 3.

In a fourth embodiment, the first surface 121 may be grained: in other words, the first surface 121 has a relief in the form of small, packed grains. In this embodiment of the invention, the physical properties of the first surface 121 are thus modified in order to attenuate the light reflections on the first surface 121. Specifically, the presence of grains on the first surface 121 diffuses the light. The roughness Ra of the graining of the first surface 121 can be quantified by measuring, over a certain length of the first surface 121, the average of the peaks and troughs of the first surface 121. Advantageously, the roughness Ra of the graining of the first surface 121 is strictly greater than 8 micrometers.

In the fourth embodiment, even if the shape of the housing 12 is liable to generate reflections of rays coming from the emitting zone 11, the light reflection is attenuated by the graining of the first surface 121.

Alternatively, the fourth embodiment could be combined with any one of the first, second and third embodiments, which would make it possible to benefit from the combined effects of the shape and the graining of the first surface 121.

In alternative or additional embodiments to the previously described embodiments, the first surface 121 may be convex, a center of curvature of the first surface 121 and the light source 1 being situated on the same side of the first surface 121.

In other words, if two spaces delimited from one another by the first surface 121 are considered, only one of the two spaces includes both the center of curvature of the first surface 121 and the light source 1.

What is claimed is:

1. A luminous device comprising an optical device and a first printed circuit board to which a light source is attached, the light source includes a light ray emitting zone and a protective housing surrounding the light ray emitting zone, a first height of the protective housing relative to a flat surface of the first printed circuit board, measured in a first direction directed toward the optical device perpendicular to the flat surface, being strictly greater than a second height of the light ray emitting zone relative to the flat surface measured in the first direction, wherein a first surface, which is oriented toward the light ray emitting zone and included between the first height and the second height, of the housing is defined so as to prevent rays coming from the light ray emitting zone from being reflected on the first surface and reaching the optical device.

2. The luminous device as claimed in claim 1, wherein the housing covers and/or protects electrical connections connecting the first printed circuit board to the light source and/or in that the first height is determined by the size of the electrical connections.

3. The luminous device as claimed in claim 1, wherein the first surface is a flat surface extending between the light ray emitting zone and an upper surface of the housing,
and in that the first surface is perpendicular both to the light ray emitting zone and to the upper surface,
a first angle formed between the first surface and the upper surface being equal to 90 degrees and having a rounded profile with a radius that is strictly less than 50 micrometers.

4. The luminous device as claimed in claim 1, wherein the first surface is a flat surface bordering the light ray emitting zone and in that
a second angle formed between the first surface and the light ray emitting zone is strictly greater than 160 degrees or
the second angle is strictly less than 90 degrees.

5. The luminous device as claimed in claim 1, wherein the first surface is grained and in that a roughness of graining of the first surface is strictly greater than 8 micrometers.

6. The luminous device as claimed in claim 1, wherein a groove is formed in an upper surface of the housing in the vicinity of the first surface, and in that the groove delimits a housing tab supporting the first surface.

7. The luminous device as claimed in claim 6, wherein the housing tab extends above the first surface.

8. The luminous device as claimed in claim 6, wherein the first surface is convex and in that a center of curvature of the first surface and the light source are situated on the same side of the first surface.
